(19) United States
(12) Patent Application Publication
(10) Pub. No.: US 2025/0255014 A1
(43) Pub. Date: Aug. 7, 2025

(54) SINGLE-PHOTON AVALANCHE DIODE AND IMAGE SENSING DEVICE INCLUDE THE SAME

(71) Applicant: SK hynix Inc., Icheon-si (KR)

(72) Inventor: Jong Chae KIM, Icheon-si (KR)

(21) Appl. No.: 19/041,231

(22) Filed: Jan. 30, 2025

(30) Foreign Application Priority Data
Feb. 1, 2024 (KR) 10-2024-0016087

(51) Int. Cl. H10F 30/225; H10F 77/00; H10F 77/14

(52) U.S. Cl. CPC H10F 30/225; H10F 77/14; H10F 77/959

(57) ABSTRACT

Single-photon avalanche diode (SPAD) and image sensing devices are disclosed. In an embodiment, a single-photon avalanche diode (SPAD) includes: an impurity junction region configured to include a plurality of depletion regions, wherein, each depletion region is an junction formed between a first doped region doped with impurities of a first conductivity type and a second doped region doped with impurities of a second conductivity type; an output node formed above the impurity junction region and in contact with one surface of a substrate; a guard-ring region formed to surround the impurity junction region; and a biasing node spaced apart from the guard-ring region and disposed at one side of the guard-ring region.

### CROSS-REFERENCE TO RELATED APPLICATION

This patent document claims the priority and benefits of Korean patent application No. 10-2024-0016087, filed on Feb. 1, 2024, the disclosure of which is incorporated herein by reference in its entirety as part of the disclosure of this patent document.

### TECHNICAL FIELD

The technology and implementations disclosed in this patent document generally relate to a single-photon avalanche diode (SPAD) and an image sensing device including the same.

### BACKGROUND

Time of Flight (TOF) technology, which has gained significant attention recently, measures the distance to a target object by emitting pulse-shaped light from a light source located near a sensor, capturing light reflected from the target object, calculating a round trip time using emitted light and reflected light, and producing the distance to the target object using the calculated round trip time.

For precise TOF measurements, the reflected light must be detected immediately after reaching the sensor. This requires highly sensitive photoelectric conversion elements.

To this end, research has been conducted on single-photon avalanche diodes (SPADs) that can be fabricated using CMOS fabrication technology. Single-photon avalanche diodes (SPADs) are optical devices with very high gain characteristics and sufficiently high photoelectric conversion efficiency to detect even a single photon.

Single-photon avalanche diodes (SPADs) can amplify emitted photons for detection using the avalanche multiplication effect, thereby enabling precise TOF measurements.

### SUMMARY

Various embodiments of the disclosed technology relate to an image sensing device designed to maximize photon detection probability.

In an embodiment of the disclosed technology, a single-photon avalanche diode (SPAD) may include: an impurity junction region configured to include a plurality of depletion regions, wherein, each depletion region is an junction formed between a first doped region doped with impurities of a first conductivity type and a second doped region doped with impurities of a second conductivity type; an output node formed above the impurity junction region and in contact with one surface of a substrate; a guard-ring region formed to surround the impurity junction region; and a biasing node spaced apart from the guard-ring region and disposed at one side of the guard-ring region.

In some implementations, the output node may be doped with impurities of the same conductivity type as the guard-ring region; and the biasing node may be doped with impurities of a different conductivity type from the output node.

In some implementations, the output node may include a higher concentration of impurities than the guard-ring region.

In some implementations, an absolute value of a difference between a second bias voltage applied to the output node and a first bias voltage applied to the biasing node may be greater than an absolute value of a breakdown voltage of the single-photon avalanche diode (SPAD).

In some implementations, the substrate may be doped with impurities of the same conductivity type as the biasing node.

In some implementations, the biasing node may have a higher concentration of impurities than the substrate.

In some implementations, the single-photon avalanche diode (SPAD) may further include a well region formed to extend from the one surface of the substrate to the other surface facing or opposite to the one surface of the substrate, wherein the output node, the impurity junction region, and the guard-ring region may be disposed within the well region.

In some implementations, the well region may be doped with impurities of a different conductivity type from the substrate; and the well region may be doped with impurities of the same conductivity type as the biasing node.

In some implementations, as the well region is located closer to one surface of the substrate, the impurities of the well region have a lower concentration.

In some implementations, the biasing node may have a higher concentration of impurities than the well region.

In some implementations, the output node may be in contact with the guard-ring region.

In some implementations, the impurity junction region has a first depth with respect to the one surface of the substrate, and the guard-ring region has a second depth with respect to the one surface of the substrate, wherein the first depth is greater than the second depth.

In some implementations, the impurity junction region has a first depth with respect to the one surface of the substrate, and the guard-ring region has a second depth with respect to the one surface of the substrate, wherein the first depth is smaller than the second depth.

In some implementations, the guard-ring region may be doped with impurities of the same conductivity type as the second doped region, wherein the guard-ring region has a higher concentration of impurities than the second doped region.

In some implementations, the biasing node may be doped with impurities of the same conductivity type as the first doped region, wherein the biasing node has a higher concentration of impurities than the first doped region.

In some implementations, the biasing node may be formed to surround the guard-ring region while being spaced apart from the guard-ring region.

In another embodiment of the disclosed technology, an imaging device may include: an array of unit pixels to detect a distance of an object from the imaging device, wherein each unit pixel includes: a single-photon avalanche diode for detecting the distance of the object from the imaging device; a quenching circuit coupled to the single-photon avalanche diode to change a bias voltage at the single-photon avalanche diode; and a read out circuit coupled to the single-photon avalanche diode to convert an output of the single-photon avalanche diode into a pulse signal, wherein the single-photon avalanche diode includes: an impurity junction region configured to include a plurality of depletion regions, wherein, each depletion region is an junction formed between a first doped region doped with impurities of a first conductivity type and a second doped region doped with impurities of a second conductivity type; an output node formed above the impurity junction region and in contact with one surface of a substrate; a guard-ring region formed to surround the impurity junction region; and a biasing node spaced apart from the guard-ring region and disposed at one side of the guard-ring.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an imaging device including an image sensing device based on an embodiment of the disclosed technology.

FIG. 2 is a circuit diagram illustrating an example of an equivalent circuit of a unit pixel included in a pixel array based on an embodiment of the disclosed technology.

FIG. 3 is a plan view illustrating an example of a single-photon avalanche diode (SPAD) based on an embodiment of the disclosed technology.

FIG. 4 is a plan view illustrating an example of a single-photon avalanche diode (SPAD) based on another embodiment of the disclosed technology.

FIG. 5 is a plan view illustrating a single-photon avalanche diode (SPAD) based on another embodiment of the disclosed technology.

FIG. 6 is a cross-sectional view illustrating an example cross-section of the single-photon avalanche diode (SPAD) taken along a first cutting line shown in FIG. 3.

FIG. 7 is a plan view illustrating a single-photon avalanche diode (SPAD) based on another embodiment of the disclosed technology.

FIG. 8 is a cross-sectional view illustrating an example cross-section of the single-photon avalanche diode (SPAD) taken along a second cutting line shown in FIG. 7.

### DETAILED DESCRIPTION

This patent document provides implementations and examples of a single-photon avalanche diode (SPAD) and an image sensing device including the SPAD. In some embodiments, the SPAD and the image sensing device including the SPAD may be used to address one or more technical and/or engineering issues and to mitigate limitations or disadvantages encountered in image sensing devices. Some implementations of the disclosed technology relate to an image sensing device that can maximize photon detection probability. To address the issues above, the disclosed technology can be implemented in some embodiments to provide a single-photon avalanche diode (SPAD) and an image sensing device including the SPAD that can enhance photon collection sensitivity while operating at a high speed.

Reference will now be made in detail to the embodiments of the disclosed technology, examples of which are illustrated in the accompanying drawings. Wherever possible, the same reference numbers will be used throughout the drawings to refer to the same or like parts. While the disclosure is susceptible to various modifications and alternative forms, specific embodiments thereof are shown by way of example in the drawings. However, the disclosure should not be construed as being limited to the embodiments set forth herein.

Hereinafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

The drawings may not be necessarily drawn to scale, and in some examples, proportions of at least some of structures in the drawings may be exaggerated to clearly show features of the embodiments or implementations. When a multilayer structure having two or more layers is disclosed in the drawings or detailed description, the relative positional relationship or arrangement order of the layers reflects a specific embodiment only and the scope or spirit of the disclosed technology is not limited thereto, and it should be noted that the relative positional relationship or arrangement order of the layers may also be changed as necessary. In addition, the drawings or detailed descriptions of a multilayer structure may not reflect all layers present in a particular multilayer structure (e.g., one or more additional layers may be present between two illustrated layers). As a specific example, when a first layer in the multilayer structure is referred to as being “on” or “over” a second layer or “on” or “over” a substrate, the first layer may be directly formed on the second layer or the substrate but may also represent a structure where one or more other layers are present between the first layer and the second layer or between the first layer and the substrate.

Hereinafter, examples of the single-photon avalanche diode (SPAD) and the image sensing device including the SPAD based on various embodiments of the disclosed technology will be described in detail with reference to the drawings.

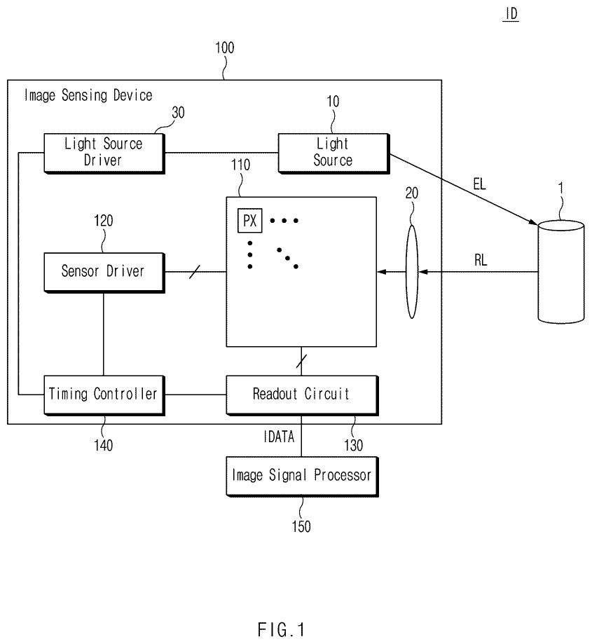

FIG. 1 is a block diagram illustrating an example of an imaging device (ID) including an image sensing device 100 according to embodiments of the disclosed technology.

Referring to FIG. 1, the imaging device (ID) may refer to a device such as a digital still camera for capturing static images or a digital video camera for recording videos. For example, the imaging device (ID) may be implemented as a digital single lens reflex (DSLR) camera, a mirrorless camera, a smartphone, and others. Examples of the imaging device (ID) may include a device that includes both a lens and an image pickup element, enabling it to capture or photograph a target object and create its image. In some implementations, the imaging device (ID) may be implemented as a Lidar (light detection and ranging) sensor.

The imaging device (ID) may include an image sensing device 100 and an image signal processor (ISP) 150.

The image sensing device 100 may be a complementary metal oxide semiconductor image sensor (CIS) for converting incident light into electrical signals. The image sensing device 100 may include a light source 10, a lens module 20, a light source driver 30, a pixel array 110, a sensor driver 120, a readout circuit 130, and a timing controller 140.

The light source 10 may emit light toward a target object 1 upon receiving a control signal from the light source driver 30. The light source 10 may be a laser diode (LD) or a light emitting diode (LED) for emitting light (e.g., near infrared (NIR) light, infrared (IR) light or visible light) having a specific wavelength band, or may be one of a Near Infrared Laser (NIR), a point light source, a monochromatic light source combined with a white lamp or a monochromator, and a combination of other laser sources. For example, the light source 10 may emit infrared light with a wavelength of 800 nm to 1000 nm. Additionally, light emitted by the light source 10 may be pulsed, with specific characteristics such as a predetermined period, amplitude, and pulse width. Although FIG. 1 shows a single light source 10 to simplify the explanation, the disclosed technology is not limited thereto, and a plurality of light sources may also be positioned near the lens module 20.

The lens module 20 may collect light reflected from the target object 1, and may allow the collected light to be focused onto pixels (PXs) of the pixel array 110. For example, the lens module 20 may include a focusing lens with a surface formed of glass or plastic or another cylindrical optical element with a surface formed of glass or plastic. The lens module 20 may include a plurality of lenses arranged to focus along an optical axis.

The light source driver 30 may operate the light source 10 under the control of the timing controller 140. In some implementations, the light source driver 30 may control or regulate waveforms (e.g., a period, amplitude, pulse width, etc.) of emitted light (EL) output from the light source 10.

The pixel array 110 may include a plurality of pixels (PXs) consecutively arranged in a two-dimensional (2D) matrix structure (e.g., consecutively arranged in a column direction and/or a row direction). Each of the plurality of pixels (PXs) may generate a pixel signal by sensing light incident through the lens module 20, under the control of the sensor driver 120.

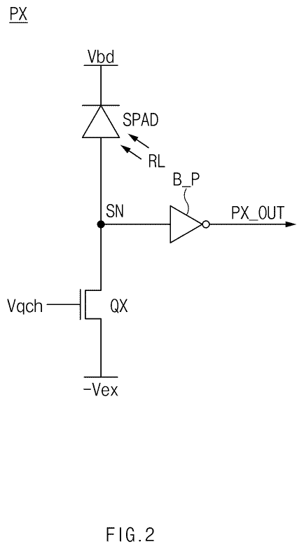

Each pixel (PX) may be an infrared pixel for generating a pixel signal by sensing incident light, including reflected light (RL) generated when emitted light (EL) from the light source 10 is reflected from the target object 1. In one embodiment, the infrared pixel may function as a depth pixel for calculating the distance to the target object 1. In another embodiment, the infrared pixel may generate an infrared image by sensing infrared light incident from a scene without relying on reflected light. In another embodiment, the pixels (PXs) may include a pixel for generating a color image by sensing visible light from a scene. Hereinafter, a specific pixel design example is described where each pixel (PX) includes a single-photon avalanche diode (SPAD) pixel for detecting the distance to the target object 1 using a direct time-of-flight (ToF) method. The detailed structure and operations of each unit pixel (PX) will be described with reference to FIGS. 2-8.

The sensor driver 120 may operate the pixels (PXs) of the pixel array 110 in response to a timing signal generated by the timing controller 140. For example, the sensor driver 120 may generate a control signal to select pixels (PXs) within at least one row line from a plurality of row lines in the pixel array 110 and control the selected pixels (PXs).

The readout circuit 130 may process pixel signals received from the pixel array 110 under the control of the timing controller 140, and may generate and store depth data for detecting the distance to the target object 1. Specifically, the readout circuit 130 may calculate a time-of-flight (TOF) corresponding to SPAD pulses generated by each pixel (PX) sensing the incident light including reflected light (RL), and may store the time-of-flight (TOF) corresponding to the SPAD pulses on a subframe basis. The readout circuit 130 may transmit the time-of-flight (TOF) stored on a subframe basis to the image signal processor 150 under the control of the timing controller 140.

The timing controller 140 may generate a timing signal to control the light source driver 30, the sensor driver 120, and the readout circuit 130. In some implementations, the timing controller 140 may generate a timing signal according to either data received from the readout circuit 130 or a request received from the image signal processor 150. In some implementations, the timing controller 140 may include a logic control circuit, a phase lock loop (PLL) circuit, a timing control circuit, a communication interface circuit and others.

The image signal processor 150 may perform at least one image signal process on image data (IDATA) received from the image sensing device 100, thereby generating the processed image data. The image signal processor 150 may reduce noise of image data (IDATA), and may perform various kinds of image signal processing (e.g., interpolation of image data (IDATA), lens distortion correction, etc.) for image-quality improvement of the image data.

The image data (IDATA) may include the time-of-flight (TOF) stored for each subframe. The image signal processor 150 may generate a histogram for one frame by accumulating data stored in units of a subframe, and may determine a target time-of-flight (TOF) for the frame based on the histogram.

The target time-of-flight (TOF) may be determined for each pixel (PX), and the image signal processor 150 may determine a target distance (e.g., the distance to the target object 1 detected by each pixel PX) based on the target time-of-flight (TOF) of each pixel (PX).

The image signal processor 150 may transmit the processed image data to a host device (not shown).

The processed image data may include information about the target distance, representing the distance from the target object 1 as detected by each pixel (PX).

In some implementations, an external device (not shown) may include a processor (e.g., an application processor) for processing image signal processed (ISP) image data received from the image signal processor 150, a memory (e.g., a non-volatile memory) for storing the ISP image data, a display device (e.g., a liquid crystal display (LCD)) for visually displaying the ISP image data, and others.

The processor included in the external device (not shown) may generate a depth image of the target object 1 based on a set or aggregate of target distances corresponding to the pixels.

The image signal processor 150 may transmit a control signal for controlling operations (e.g., whether or not to operate, an operation timing, an operation mode, etc.) of the image sensing device 100 to the image sensing device 100.

FIG. 2 is a circuit diagram illustrating an example of a part of a unit pixel (PX) included in a pixel array with a single-photon avalanche diode (SPAD) based on an embodiment of the disclosed technology.

Referring to FIG. 2, the unit pixel (PX) may include a single-photon avalanche diode (SPAD), a quenching circuit (QX), and a SPAD output circuit in form of a pixel buffer (B_P).

The single-photon avalanche diode (SPAD) may detect a single photon reflected by the target object 1, and may generate a voltage pulse corresponding to the detected single photon.

The SPAD may operate as a photodiode that includes a photosensitive P-N junction. Since an avalanche breakdown is triggered by a single photon incident in a Geiger mode in which a reverse bias voltage is applied, when a cathode-anode voltage (e.g., voltage between the cathode and anode) is higher than a breakdown voltage, the SPAD may generate a voltage pulse. In some implementations, this process, in which an avalanche breakdown is triggered by a single photon to generate a voltage pulse, is defined as an avalanche process.

The SPAD may include a cathode and an anode. One of these terminals (the cathode and the anode) may serve as the output node for the voltage pulse, and the other terminal may function as a biasing node.

The equivalent circuit diagram shown in FIG. 2 represent the SPAD that includes the anode serving as an output node and the cathode serving as a biasing node.

The cathode of the SPAD may receive a first bias voltage (Vbd), which is a reverse bias voltage capable of operating the single-photon avalanche diode in the Geiger mode. The first bias voltage (Vbd) may be a voltage that applies a reverse bias voltage higher than the breakdown voltage to the SPAD.

For example, the first bias voltage (Vbd) may be a voltage such that the value obtained by subtracting a second bias voltage (−Vex) from the first bias voltage (Vbd) results in a negative voltage with an absolute value greater than the breakdown voltage. The anode of the SPAD may be connected to a sensing node (SN), and the SPAD may output a voltage pulse generated by sensing photons to the sensing node (SN).

After a voltage pulse is generated due to avalanche breakdown and the voltage of the sensing node (SN) increases, the quenching circuit (QX) may perform a quenching operation to return the voltage of the sensing node (SN) to the second bias voltage (−Vex) (or to return the SPAD to the Geiger mode). One terminal of the quenching circuit (QX) may receive the second bias voltage (−Vex) such that a reverse bias voltage capable of operating the SPAD in the Geiger mode can be applied to the SPAD.

For example, the second bias voltage (−Vex) may be a voltage such that the value obtained by subtracting the second bias voltage (−Vex) from the first bias voltage (Vbd) results in a negative voltage with an absolute value greater than the breakdown voltage. The other terminal of the quenching circuit (QX) may be connected to the sensing node (SN), and when the quenching circuit (QX) is turned on, the voltage of the sensing node (SN) may return to the second bias voltage (−Vex).

In some implementations, the quenching circuit (QX) may be an N-channel metal-oxide semiconductor (NMOS) transistor that receives a quenching control voltage (Vqch) through a gate terminal thereof. The quenching control voltage (Vqch) may have a turn-on voltage when the voltage of the sensing node (SN) increases due to generation of a voltage pulse, and may have a turn-off voltage when the voltage of the sensing node (SN) returns to the second bias voltage (−Vex). For example, the quenching control voltage (Vgch) may be supplied from the sensor driver 120 or may be supplied from the sensing node (SN).

The SPAD output circuit in this example is a pixel buffer (B_P) that samples an analog voltage pulse generated at the sensing node SN and convert the sampled analog voltage pulse into a digital pulse signal (e.g., a single-photon avalanche diode (SPAD) pulse). Here, the sampling method may include converting the voltage pulse into a pulse signal with a logic level of 0 or 1, depending on whether the level of the voltage pulse is a threshold level or higher. However, the disclosed technology is not limited to the sampling method discussed above.

The analog voltage pulse generated at the sensing node (SN) may exhibit a waveform that momentarily increases from the second bias voltage (−Vex) due to the avalanche process and then returns to the second bias voltage (−Vex) due to the quenching operation. Accordingly, since the pixel buffer (B_P) converts the voltage pulse into a digital pulse signal, the pixel signal (PX_OUT) serving as the output signal of the pixel buffer (B_P) may exhibit a waveform in which the pixel signal (PX_OUT) has a logic level of 0, then momentarily changes to a logic level of 1 when the voltage pulse occurs, and finally returns to the logic level (or a logic low level) of 0.

In some implementations, the pulse of the pixel signal (PX_OUT) generated by the pixel buffer (B_P) may hereinafter be referred to as a single-photon avalanche diode (SPAD) pulse.

Although FIG. 2 illustrates the single-photon avalanche diode (SPAD) as receiving the first bias voltage (Vbd) through the cathode, the disclosed technology is not limited thereto, and it should be noted that the SPAD may also receive the first bias voltage (Vbd) through the anode. When the anode receives the first bias voltage (Vbd), the anode may serve as a biasing node and the cathode may serve as an output node. However, in this case, the voltage levels of the first and second bias voltages (Vbd, −Vex) may be configured to enable the SPAD to operate in the Geiger mode.

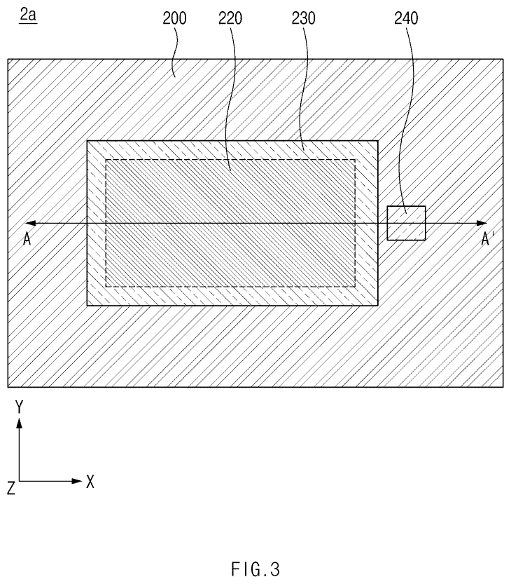

FIG. 3 is a plan view illustrating an example of a single-photon avalanche diode (SPAD) based on an embodiment of the disclosed technology.

Each of the unit pixel (PX) of FIG. 1 and the unit pixel (PX) of FIG. 2 may include one single-photon avalanche diode (SPAD).

Referring to the plan view (2a) of FIG. 3, the single-photon avalanche diode (SPAD) may include a substrate 200, an output node 220, a guard-ring region 230, and a biasing node 240.

In FIG. 3, the output node 220 may be an anode region of the SPAD, and the biasing node 240 may be a cathode region of the SPAD.

The plan view (2a) of FIG. 3 may illustrate the SPAD on one surface of the substrate 200 in a direction (e.g., Z-axis direction) perpendicular to the surface of the substrate 200.

The single-photon avalanche diode (SPAD) may further include an impurity junction region between a p doped region and a n-doped region (not shown) that collects photons to produce an associate electrical signal such as a photocurrent due to the absorption of the collected photos. The impurity junction region (not shown) may overlap with the output node 220, and is omitted from the plan view (2a) of FIG. 3.

The substrate 200 may include a bulk monocrystalline silicon wafer, a silicon on insulator (SOI) wafer, a Si—Ge compound semiconductor wafer, a silicon epitaxial layer wafer, etc.

The substrate 200 may be a monocrystalline silicon wafer doped with impurities of a first conductivity type (e.g., N-type impurities).

The area visible in the plan view (2a) may be one surface (or one side) of the substrate 200. For example, one surface of the substrate 200 may be a front surface (or a front side) of the substrate 200. In some implementations, control circuits for controlling the SPAD may be arranged at one surface of the substrate 200.

The control circuits may be driven by the sensor driver 120 and may provide a preset bias voltage to an output node 220 included in the SPAD and/or a biasing node 240 included in the SPAD.

The surface facing or opposite to one surface of the substrate 200 may be referred to as the other surface of the substrate 200, and the other surface of the substrate 200 may be referred to as a back surface (or a back side). In some implementations, light may be incident upon the other surface of the substrate 200, and an optical member such as an optical filter or a microlens may be disposed on the other surface of the substrate 200.

The single-photon avalanche diode (SPAD) may include the output node 220 in contact with one surface of the substrate 200. An impurity junction region (not shown) may be disposed below the output node 220.

The output node 220 may overlap the impurity junction region (not shown). The impurity junction region (not shown) may be a region where carriers are generated by incident photons.

The output node 220 may be used as a region to which the second bias voltage is applied. Applying the second bias voltage to the output node 220 may generate a high electric field, which affects carriers generated in the impurity junction region (not shown). The high electric field may induce an avalanche phenomenon as carriers move, amplifying carriers generated by photons. By using the amplified carriers, the image sensing device 100 can detect small amounts of photons.

The output node 220 may refer to a region doped with impurities of a second conductivity type (e.g., P-type impurity).

The output node 220 may be formed to be doped with the second conductivity-type impurities (P-type impurities) to a predetermined depth from one surface of the substrate 200.

When viewed from the direction (e.g., Z-axis direction) perpendicular to one surface of the substrate 200, the output node 220 may have a polygonal shape (e.g., a rectangular shape) to ensure the output node 220 to overlap the impurity junction region (not shown).

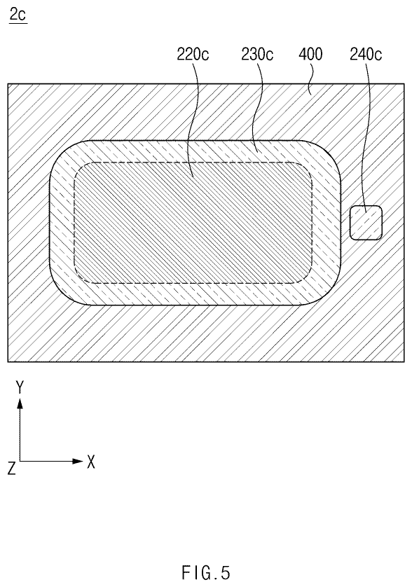

In another embodiment, the output node 220 may have a rectangular shape with rounded vertices, and the output node 220 having a rectangular shape with rounded vertices will be described in detail later with reference to FIG. 5.

In another embodiment, the output node 220 may have various shapes, for example, a square shape, a circular shape, an oval shape, and the like.

The output node 220 may be in contact with a guard-ring region 230. The guard-ring region 230 may be formed to surround the impurity junction region (not shown).

In another embodiment, the output node 220 and the guard-ring area 230 may be formed to be spaced apart from each other.

The guard-ring region 230 may extend from one surface of the substrate 200 to the other surface of the substrate 200, and may be formed to surround the output node 220.

The guard-ring region 230 may be doped with the second conductivity-type impurities (e.g., P-type impurities).

The concentration of impurities included in the output node 220 may be higher than the concentration of impurities included in the guard-ring region 230.

To achieve high light-receiving efficiency in the SPAD, a uniform electric field must be generated in the impurity junction region (not shown) by applying a bias voltage to both the output node 220 and the biasing node 240. Specifically, the bias voltage applied to the output node 220 and the biasing node 240 creates a uniform electric field within a depletion region of the impurity junction region (not shown). The depletion region may refer to a region in which impurities of different conductivity types within the impurity junction region (not shown) are bonded.

Due to the structural characteristics of the SPAD, when the p-n junction in the impurity junction region is reversely biased, a breakdown may occur at the outer edge of the impurity junction region (not shown) before photons are introduced into the SPAD.

In this case, breakdown that occurs either at the outer edge of the impurity junction region (not shown) or at the outer edge of the output node 220, before the incident light enters the SPAD, may be referred to as premature edge breakdown (PEB). When such a PEB occurs, it becomes difficult to accurately measure the number of photons incident upon the SPAD. Therefore, the guard-ring region 230 may be formed around the output node 220 and the impurity junction region.

The impurity concentration of the guard-ring region 230 may be higher than the impurity concentration of the second conductivity-type impurity region (e.g., a second doped region) included in the impurity junction region (not shown).

The biasing node 240 may refer to a region that is adjacent to the guard-ring region 230 and doped with the first conductivity-type impurities (e.g., N-type impurities).

The biasing node 240 may be a region to which a first bias voltage is applied. The impurity concentration of the biasing node 240 may be higher than the impurity concentration of the first conductivity-type impurity region (e.g., a first doped region) included in the impurity junction region (not shown).

Additionally, when the substrate 200 is doped with the first conductivity-type impurities, the concentration of the first conductivity-type impurities included in the biasing node 240 may be higher than the concentration of the first conductivity-type impurities included in the substrate 200.

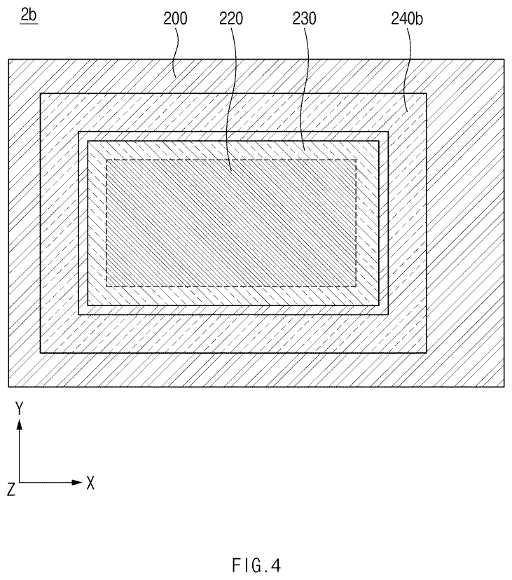

The biasing node 240 may have a square, polygonal, or circular shape. By adjusting the shape of the biasing node 240, the first bias voltage can mitigate electric field stress that occurs in the corner or vertex region of the biasing node 240. The shape of the biasing node 240 will be described in detail later with reference to FIGS. 4 and 5.

FIG. 4 is a plan view (2b) illustrating an example of a single-photon avalanche diode (SPAD) based on another embodiment of the disclosed technology.

Referring to the plan view (2b) of FIG. 4, a biasing node 240b may be formed to surround a guard-ring region 230.

Since the biasing node 240b is formed to surround the guard-ring region 230, charges can be easily output through the biasing node 240b. When the biasing node 240b has a shape surrounding the guard-ring region 230, a sufficient area of the biasing node 240b can be secured. Since the area of the biasing node 240b is sufficiently secured, carriers amplified in the impurity junction region (not shown) can be easily output through the biasing node 240b.

The depth of the biasing node 240b in the direction (e.g., Z-axis direction) perpendicular to one surface of the substrate 200 may vary depending on the charge collection ability of the biasing node 240b. For example, in order to easily collect carriers amplified in the impurity junction region (not shown) that is located deep in the direction (e.g., Z-axis direction) perpendicular to one surface of the substrate 200, the biasing node 240b may be formed to have the same depth as the impurity junction region (not shown).

FIG. 5 is a plan view (2c) illustrating a single-photon avalanche diode (SPAD) based on another embodiment of the disclosed technology.

Referring to the plan view (2c) of FIG. 5, an output node 220c having a rectangular shape with rounded vertices, a guard-ring region 230c having a rectangular shape with rounded vertices, and a biasing node 240c having a rectangular shape with rounded vertices are shown.

Since the vertices of the output node 220c, the guard-ring region 230c, and the biasing node 240c are formed to have a rounded rectangular shape, electric field stress that may occur at the vertices and/or corners of the output node 220c, the guard-ring region 230c, and the biasing node 240c can be mitigated.

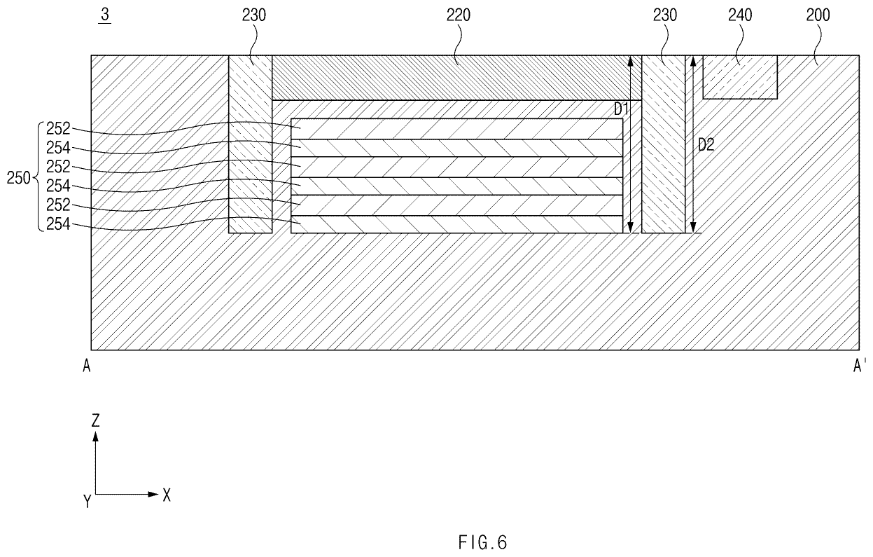

FIG. 6 is a cross-sectional view (3) illustrating an example cross-section of the single-photon avalanche diode (SPAD) taken along a first cutting line A-A′ shown in FIG. 3.

The cross-sectional view (3) shown in FIG. 6 may illustrate a cross-section of the SPAD taken along the first cutting line A-A′ shown in FIG. 3.

Referring to FIG. 6, the SPAD may include a substrate 200, an output node 220, a guard-ring region 230, a biasing node 240, and an impurity junction region 250.

To simplify the explanation, the same contents as those described above will herein be omitted.

Referring to FIG. 6, the impurity junction region 250 may include a plurality of first doped regions 252 and a plurality of second doped regions 254.

Each of the first doped regions 252 may be a region doped with impurities of the first conductivity type (e.g., N-type impurities), and each of the second doped regions 254 may be a region doped with impurities of the second conductivity type (e.g., P-type impurities).

The concentration of the first conductivity-type impurities included in the first doped region 252 may be less than or equal to the concentration of the first conductivity-type impurities included in the substrate 200. Additionally, the concentration of the first conductivity-type impurities included in the first doped region 252 may be less than the concentration of the first conductivity-type impurities included in the biasing node 240.

The concentration of the second conductivity-type impurities included in the second doped region 254 may be less than the concentration of the second conductivity-type impurities included in the output node 220, and may be less than the concentration of the second conductivity-type impurities included in the guard-ring region 230.

Although the impurity junction region 250 is shown as including three first doped regions 252 and three second doped regions 254 in FIG. 6, this is merely an example, and it should be noted that the number of the first doped regions 252 included in the impurity junction region 250 and the number of the second doped regions 254 included in the impurity junction region 250 may vary.

Since the impurity junction region 250 includes the plurality of first doped regions 252 and the plurality of second doped regions 254, the area size of a depletion region (or an amplification region) to be formed at a junction between the first doped region 252 and the second doped region 254 may be adjusted. Here, the depletion region may be a region in which the regions 252 and 254 doped with impurities of different conductivity types in the impurity junction region 250 are joined.

The depletion region may refer to a region in which carriers generated by photons initiate the avalanche phenomenon.

In an embodiment of the disclosed technology, since the plurality of depletion regions is formed in the impurity junction region 250, capacitance of the SPAD can be reduced and at the same time the photon collection ability can be improved.

Since the impurity junction region 250 including the plurality of depletion regions is formed below the output node 220, the absolute value of the breakdown voltage that enables carriers to be amplified and detected can be reduced.

In other words, since the impurity junction region 250 is formed as described above, the carriers can trigger the avalanche phenomenon even if the absolute value of the difference between the second bias voltage applied to the output node 220 and the first bias voltage applied to the biasing node (e.g., an absolute value obtained by subtracting the second bias voltage applied to the output node 220 from the first bias voltage applied to the biasing node 240) is small.

When the capacitance of the SPAD decreases, a time required to detect carriers amplified by the avalanche phenomenon can be shortened. In addition, when the capacitance of the SPAD decreases, a dead time during which a voltage pulse caused by photons is first detected and quenching of the SPAD is then performed can be shortened.

Since the impurity junction region 250 is formed to have the plurality of first doped regions 252 and the plurality of second doped regions 254, a depth at which the depletion region (also referred to as “amplification region”) is to be formed with respect to one surface of the substrate 200 can be adjusted.

By adjusting the depth at which the depletion region is to be formed, collection sensitivity for each incident light of the SPAD can be adjusted. More specifically, as the depth at which the depletion region is to be formed with respect to one surface of the substrate 200 increases, collection sensitivity of light having a long wavelength band may increase.

Referring to FIG. 6, the depth D1 of the impurity junction region 250 with respect to one surface of the substrate 200 may be adjusted according to the depth D2 of the guard-ring region 230 with respect to one surface of the substrate 200.

Referring to the cross-sectional view (3) of FIG. 6, the depth D1 of the impurity junction region 250 may be equal to the depth D2 of the guard-ring region 230.

In another embodiment, the impurity junction region 250 may be located deeper than the guard-ring region 230 so that the depth D1 of the impurity junction region 250 is greater than the depth D2 of the guard-ring region 230.

The guard-ring region 230 may be a region doped with the second conductivity-type impurities having a lower concentration than the output node 220. Here, the depth D2 of the guard-ring region 230 may be adjusted according to electrical characteristics of the SPAD.

For example, when premature edge breakdown (PEB) mainly occurs at the outer edge of the output node 220 of the SPAD, the depth D2 of the guard-ring region 230 may be smaller than the depth D1 of the impurity junction region 250.

Alternatively, when premature edge breakdown (PEB) mainly occurs at the outer edge of the impurity junction region 250, the depth D2 of the guard-ring region 230 may be greater than the depth D1 of the impurity junction region 250.

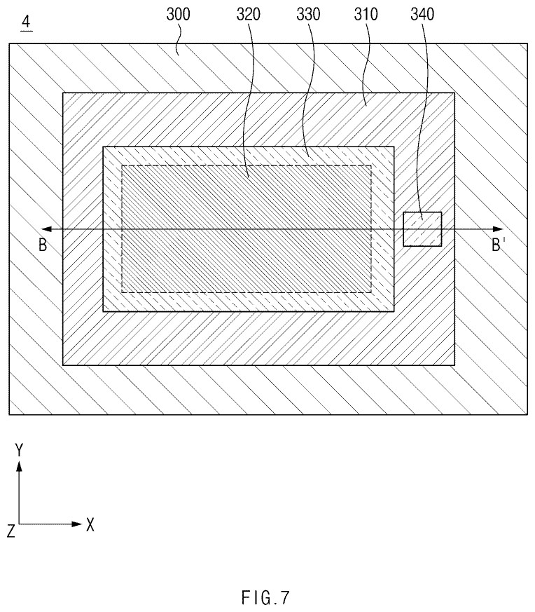

FIG. 7 is a plan view (4) illustrating a single-photon avalanche diode (SPAD) based on another embodiment of the disclosed technology.

Referring to the plan view (4) of FIG. 7, the SPAD may include a substrate 300, a well region 310, an output node 320, a guard-ring region 330, and a biasing node 340.

The plan view (4) may illustrate the SPAD when viewed in a direction (e.g., Z-axis direction) perpendicular to one surface of the substrate 300.

To simplify the explanation, the same contents as those described with reference to FIGS. 1 to 6 will herein be omitted.

The SPAD shown in the plan view (4) may include a substrate 300 containing the second conductivity-type impurities (e.g., P-type impurities) and a well region 310 containing the first conductivity-type impurities (e.g., N-type impurities).

For example, the substrate 300 may be a monocrystalline silicon wafer doped with the second conductivity-type impurities (e.g., P-type impurities).

The well region 310 may be a region that is formed within the substrate 300 and extends from one surface of the substrate 300 to the other surface of the substrate 300.

The well region 310 may be a region doped with the first conductivity-type impurities (e.g., N-type impurities).

The output node 320, the guard-ring region 330, the biasing node 340, and the impurity junction region (not shown) may be formed in the well region 310.

The well region 310 may be formed by implanting the first conductivity-type impurities in at least a portion of the substrate 300.

According to the present embodiment, the well region 310 may have different concentrations of impurities depending on the depth to one surface of the substrate 300.

For example, as the well region 310 is located closer to one surface of the substrate 300, the concentration of the first conductivity-type impurities may decrease.

The characteristics of the impurity junction region (not shown) formed in the well region 310 may be adjusted by varying the impurity concentration of the well region 310.

For example, the concentration of the first conductivity-type impurities included in the well region 310 adjacent to one surface of the substrate 300 may be adjusted to be lower than the concentration of the first conductivity-type impurities (i.e., the first doped region) included in the impurity junction region (not shown). Conversely, the concentration of the first conductivity-type impurities included in the well region 310 located far from the one surface of the substrate 300 may be adjusted to be higher than the impurity concentration of the first doped region. This adjustment enables precise control of the depth at which the depletion region is formed below the output node 320.

When the depletion region is formed below the output node 320, the collection sensitivity of the SPAD collecting photons of a long-wavelength band may increase. Additionally, the capacitance of the SPAD may decrease, so that the photon collection ability may increase, and the dead time required for quenching may decrease.

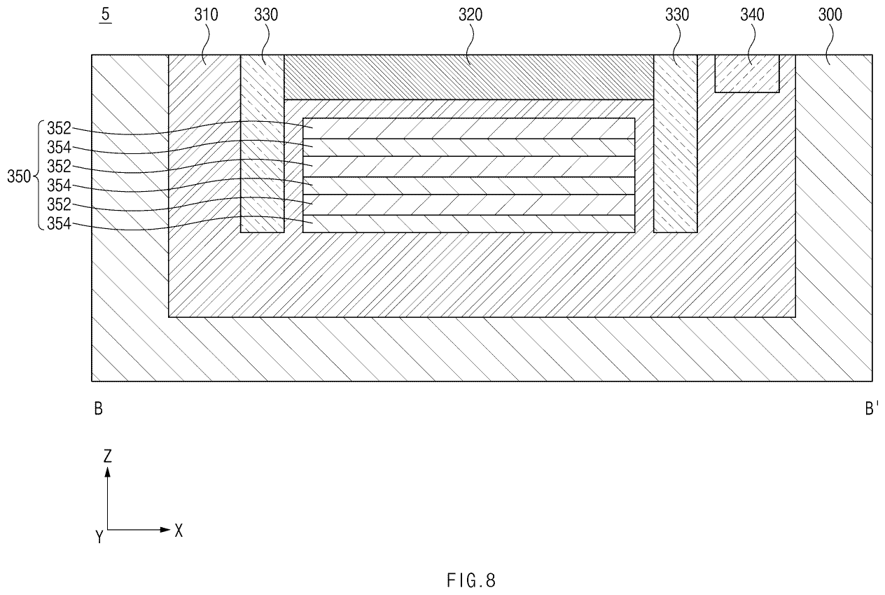

FIG. 8 is a cross-sectional view illustrating an example cross-section of the single-photon avalanche diode (SPAD) taken along a second cutting line B-B′ shown in FIG. 7.

Referring to FIG. 8, the SPAD may include a substrate 300, a well region 310, an output node 320, a guard-ring region 330, a biasing node 340, and an impurity junction region 350.

To simplify the explanation, the same contents as those described with reference to FIGS. 1 to 6 will herein be omitted.

Referring to FIG. 8, the well region 310 may be a region extending from one surface of the substrate 300 to the other surface of the substrate 300.

The output node 320, the guard-ring region 330, the biasing node 340, and the impurity junction region 350 may be formed in the well region 310.

The impurity junction region 350 may include a plurality of first doped regions 352 and a plurality of second doped regions 354.

The first doped region 352 may be a region doped with the first conductivity-type impurities (e.g., N-type impurities), and the second doped region 354 may be a region doped with the second conductivity-type impurities (e.g., P-type impurity).

The concentration of the first conductivity-type impurities included in the first doped region 352 may be less than the concentration of the first conductivity-type impurities included in the biasing node 340.

The concentration of the second conductivity-type impurities included in the second doped region 354 may be less than or equal to the concentration of the second conductivity-type impurities included in the substrate 300.

Although the impurity junction region 350 is shown as including three first doped regions 352 and three second doped regions 354 in FIG. 8, this is merely an example, and it should be noted that the number of the first doped regions 352 included in the impurity junction region 350 and the number of the second doped regions 354 included in the impurity junction region 350 may vary.

Since the impurity junction region 350 includes the plurality of first doped regions 352 and the plurality of second doped regions 354, the area of a depletion region (or an amplification region) to be formed at a junction between the first doped region 352 and the second doped region 354 may be adjusted.

In an embodiment, the characteristics of the SPAD may be controlled by adjusting the concentration of the first conductivity-type impurities included in the well region 310 depending on the depth from one surface of the substrate 300.

Additionally, since the depth of the guard-ring region 330 with respect to one surface of the substrate 300 is adjusted, premature edge breakdown (PEB) that may occur at the outer edge of the output node 320 or the impurity junction region 350 can be prevented.

As is apparent from the above description, the image sensing device based on some embodiments of the disclosed technology may exhibit improved photon collection sensitivity and can operate at a high speed.

The embodiments of the disclosed technology may offer a variety of effects that can be directly or indirectly recognized through the above-mentioned patent document.

Although a number of illustrative embodiments have been described, it should be understood that modifications and enhancements to the disclosed embodiments and other embodiments can be devised based on what is described and/or illustrated in this patent document.

What is claimed is:

1. A single-photon avalanche diode comprising:
an impurity junction region configured to include a plurality of depletion regions, wherein, each depletion region is a junction formed between a first doped region doped with impurities of a first conductivity type and a second doped region doped with impurities of a second conductivity type;
an output node formed above the impurity junction region and in contact with one surface of a substrate;
a guard-ring region formed to surround the impurity junction region; and
a biasing node spaced apart from the guard-ring region and disposed at one side of the guard-ring region.

2. The single-photon avalanche diode according to claim 1,
wherein:
the output node is doped with impurities of a same conductivity type as the guard-ring region, and
the biasing node is doped with impurities of a different conductivity type from the output node.

3. The single-photon avalanche diode according to claim 2, wherein:
the output node includes a higher concentration of impurities than the guard-ring region.

4. The single-photon avalanche diode according to claim 1, wherein:
an absolute value of a difference between a second bias voltage applied to the output node and a first bias voltage applied to the biasing node is greater than an absolute value of a breakdown voltage of the single-photon avalanche diode.

5. The single-photon avalanche diode according to claim 1, wherein:
the substrate is doped with impurities of a same conductivity type as the biasing node.

6. The single-photon avalanche diode according to claim 5, wherein:
the biasing node has a higher concentration of impurities than the substrate.

7. The single-photon avalanche diode according to claim 1, further comprising:
a well region formed to extend from the one surface of the substrate to another surface facing or opposite to the one surface of the substrate,
wherein the output node, the impurity junction region, and the guard-ring region are disposed within the well region.

8. The single-photon avalanche diode according to claim 7, wherein:
the well region is doped with impurities of a different conductivity type from the substrate, and
the well region is doped with impurities of a same conductivity type as the biasing node.

9. The single-photon avalanche diode according to claim 7, wherein:
as the well region is located closer to one surface of the substrate, the impurities of the well region have a lower concentration.

10. The single-photon avalanche diode according to claim 8, wherein:
the biasing node has a higher concentration of impurities than the well region.

11. The single-photon avalanche diode according to claim 1, wherein:
the output node is in contact with the guard-ring region.

12. The single-photon avalanche diode according to claim 1, wherein:
the impurity junction region has a first depth with respect to the one surface of the substrate, and the guard-ring region has a second depth with respect to the one surface of the substrate, wherein the first depth is greater than the second depth.

13. The single-photon avalanche diode according to claim 1, wherein:
the impurity junction region has a first depth with respect to the one surface of the substrate, and the guard-ring region has a second depth with respect to the one surface of the substrate, wherein the first depth is smaller than the second depth.

14. The single-photon avalanche diode according to claim 1, wherein:
the guard-ring region is doped with impurities of a same conductivity type as the second doped region,
wherein the guard-ring region has a higher concentration of impurities than the second doped region.

15. The single-photon avalanche diode according to claim 1, wherein:
the biasing node is doped with impurities of a same conductivity type as the first doped region,
wherein the biasing node has a higher concentration of impurities than the first doped region.

16. The single-photon avalanche diode according to claim 1, wherein:
the biasing node is formed to surround the guard-ring region and is spaced apart from the guard-ring region.

17. An imaging device, comprising:
an array of unit pixels to detect a distance of an object from the imaging device, wherein each unit pixel includes:
a single-photon avalanche diode for detecting the distance of the object from the imaging device;
a quenching circuit coupled to the single-photon avalanche diode to change a bias voltage at the single-photon avalanche diode; and
a read out circuit coupled to the single-photon avalanche diode to convert an output of the single-photon avalanche diode into a pulse signal,
wherein the single-photon avalanche diode includes:
an impurity junction region configured to include a plurality of depletion regions, wherein, each depletion region is a junction formed between a first doped region doped with impurities of a first conductivity type and a second doped region doped with impurities of a second conductivity type;
an output node formed above the impurity junction region and in contact with one surface of a substrate;
a guard-ring region formed to surround the impurity junction region; and
a biasing node spaced apart from the guard-ring region and disposed at one side of the guard-ring.
